(19) United States
(12) Patent Application Publication
(10) Pub. No.: US 2010/0211509 A1
(43) Pub. Date: Aug. 19, 2010

(54) RESOURCE MONITORING DEVICE

(76) Inventor: Richard B. Jacobs, Ocean Township, NJ (US)

Correspondence Address: FAY SHARPE LLP, 1228 Euclid Avenue, 5th Floor, The Halle Building, Cleveland, OH, 44115, US

(21) Appl. No.: 12/707,226

(22) Filed: Feb. 17, 2010

Related U.S. Application Data
(60) Provisional application No. 61/153,050, filed on Feb. 17, 2009.

(51) Int. Cl. G06Q 50/00; G01R 21/06; G06Q 10/00; G06Q 30/00; G06F 19/00

(52) U.S. Cl. 705/302; 702/62; 705/303; 705/317; 705/400

(57) ABSTRACT

A resource monitoring system that includes at least one resource monitoring device. The resource monitoring device is integrated in, connected to and/or interconnected to at least one resource consuming device. A remote monitoring location can optionally be provided to receive information from one or more resource monitoring device and to provide information concerning and/or related to at least one resource consuming device.

The present invention claims priority on U.S. Provisional Patent Application Ser. No. 61/153,050 filed Feb. 17, 2009, which is fully incorporated herein by reference.

The present invention relates to resource monitoring systems and more particularly to a monitoring device which can be connected to, interconnected with and/or incorporated in a resource consuming device.

### BACKGROUND OF THE INVENTION

The monitoring of the amount of resource consumption such as electricity consumption has increased in importance in recent times due to rising energy costs. As a result, there has been an increased interest in maximizing the efficiency of energy consuming devices so as to minimize the energy costs associated with the operation of such devices. There has also been a recent trend with manufacturers to develop appliances having an “Energy Star” rating to inform consumers that such appliances are more energy efficient and thereby consume less energy, resulting in a lower operating cost for such appliance. These appliances usually include information about the average energy consumption of such appliance; however, actual energy consumption of such appliance is not available when the appliance is operated in a particular environment. The energy consumption by many other types of appliances which do not include an energy star rating is difficult to even estimate the cost of energy consumption during operation. As a result, it is difficult, if not impossible, to determine which appliances or other energy consuming devices are running efficiently or inefficiently in a household and/or commercial setting. In view of the existing limitations in the industry, there is a need for a device and a method for measuring and monitoring the resource consumption of one or more resource consuming devices.

### SUMMARY OF THE INVENTION

The present invention is particularly directed to a device for monitoring and/or measuring the amount of a resource being consumed by a particular device. For purposes of this invention, a resource includes electricity; liquid (e.g., water, oil, fuel oil, kerosene, diesel fuel, gasoline, liquid hydrogen, liquid nitrogen, methanol, etc.); and air and or other types of gasses (e.g., hydrogen, nitrogen, methane, natural gas, etc.) that are pressurize or not pressurized. Electricity, natural gas and water are currently the most common resources consumed by typical household consumers and businesses. Other types of resources that are less commonly used by typical consumers and businesses (e.g., fuel oil and/or kerosene to provide heat for cooking and/or heating, liquid nitrogen to cool computer systems, etc.) can also be monitored by the resource monitoring device of the present invention. In various types of industrial applications, pressurized gasses are used to operate various types of equipment, thus such pressurized gas is also a consumable resource when provided in canisters or cylinders, and the monitoring of this resource can also be accomplished by the resource monitoring device of the present invention. The emerging technologies associated with fuel cells may ultimately give rise to the mass consumption by consumers of hydrogen gas, methanol, or some other resource. The monitoring and/or measuring of these and any other consumable resource are contemplated by this invention. One of the basic premises of the present invention is to monitor and/or measure at least one consumable resource and to provide information to a consumer about one or more devices and/or systems that are consuming the at least one consumable resource. The information obtained by the resource monitoring device of the present invention can be used in a variety of ways. For example, the information obtained by the resource monitoring device can be used to a) monitor the resource consumption of the one or more resource consuming devices and/or systems, b) provide a breakdown of resource consumption (e.g., time, date, consumption rate, etc.) by one or more resource consuming devices and/or systems, c) modify and/or suggest modifications to the user of one or more resource consuming devices and/or systems (e.g., suggest more efficient devices, adjust operation time of the resource consuming device. etc.), d) provide information about the efficiency of the one or more resource consuming devices and/or systems, e) provide information to a user about whether the one or more resource consuming devices and/or systems in operating normally or abnormally (e.g., engine failing thus drawing more power than usual, engine broken thus not drawing any energy, etc.), f) control the operation of one or more resource consuming device (e.g., enable/disable flow of resource to resource consuming device, etc.), g) provide information to the user on how to improve the efficiency of the one or more resource consuming devices and/or systems, h) suggest operation times (e.g., night time operation when electricity rates are lower, etc.) and/or operating parameters (e.g., suggest increase/decrease in thermostat during certain portions of day, suggest watering yard in morning or late afternoon, etc.) of one or more resource consuming device to control costs of using the one or more resources, i) suggest websites and/or obtain information on the internet regarding one or more of the resource consuming devices being monitored (e.g., obtain recall or repair notices from manufacturer, obtain suggested repair and check-up intervals for one or more of the resource consuming devices being monitored, compare resource consumption to published resource consumption rates, etc.), j) provide graphical and data information regarding each resource consuming device being monitored and/or a group of resource consuming devices being monitored, k) enable a user to locally and/or remotely access information about one or more resource consuming devices being monitored via an electronic device (e.g., computer, phone, blackberry, etc.), and/or locally and/or remotely control one or more resource consuming devices being monitored via an electronic device (e.g., computer, phone, blackberry, etc.), and/or 1) enable a user to locally and/or remotely access information about one or more resource monitoring devices via an electronic device (e.g., computer, phone, blackberry, etc.), and/or locally and/or remotely reprogram and/or control one or more resource monitoring devices via an electronic device (e.g., computer, phone, blackberry, etc.). As can be appreciated, other and/or alternative information can be provided to the user based on the information monitored and/or measured. Furthermore, it can be appreciated that there can be other and/or alternative uses of the information that is monitored and/or measured by the resource monitoring device of the present invention.

In one non-limiting aspect of the present invention, there is provided a resource monitoring device that is designed to measure and/or monitor one or more parameters of a resource and/or resource consuming device over one or more periods of time. The type of parameters measured and/or monitored by the resource monitoring device will depend on the type of resource and/or resource consuming device being monitored. For instance, when the monitored/measured resource is electricity and/or a resource consuming device that consumes electricity (e.g., oven, central air system, refrigerator, lights, washing machine, industrial equipment, etc.), the resource monitoring device can be designed to measure and/or monitor the voltage, the current frequency, maximum current level, minimum current level, average current level, KWH, maximum consumption, minimum consumption, average consumption, timer period of use, etc. When the resource is natural gas and/or a resource consuming device that consumes natural gas (e.g., gas fireplace, gas water heater, gas dryer, gas stove, gas furnace, etc.), the resource monitoring device can be designed to measure and/or monitor the gas flow rate, the gas pressure, the volume of gas consumed, time period of use, etc. When the resource is water and/or a resource consuming device that uses water (e.g., sink faucet, toilet, water heater, outside sprinkler, bathtub, shower, etc.), the resource monitoring device can be designed to measure and/or monitor the water flow rate, the water pressure, the gallons of water consumed, time period of use, etc. When the resource is fuel oil or kerosene and/or a resource consuming device that consumes fuel oil or kerosene (e.g., stove, furnace, etc.), the resource monitoring device can be designed to measure and/or monitor the flow rate of fuel oil or kerosene, the volume of fuel oil or kerosene consumed, time period of use, etc. Indeed, any parameter that might be used to provide information about the consumption of a resource by one or more resource consuming devices and/or systems can be measured and/or monitored by the resource monitoring device. As can also be appreciated, any increment of measurement can be made (e.g., resource consumed per second, resource consumed per minute, resource consumed per hour, resource consumed per day, resource consumed per month, resource consumed per year, watt, kilowatt, quart, gallon, cubic foot, etc.). This measured and/or monitored information by the resource monitoring device can be correlated to a variety of parameters such as, but not limited to, 1) a time period (e.g., time of day, day, portion of day (e.g., morning, afternoon, etc.,), month, portion of month (e.g., beginning or month, end of month, etc.), year, portion of year (e.g., summer, winter, fall, spring, etc.), decade, century; 2) the identity of the resource consuming device [Household devices—oven, stove, cooking hood, warming drawer, food mixer, food steamer, juicer, deep fryer, toaster, toaster oven, crook pot, tea maker, food slicer, popcorn maker, fondue pot, ice cream maker, bread maker, electric grill, electric skillet, clothes iron, clothes steamer, towel warmer, sauna, shower steamer, heating light, electric can opener, coffee grinder, floor steamer, floor cleaner, washing machine, dryer, central or window air conditioner, microwave, coffee maker, dishwasher, wine cooler, refrigerator, freezer, cable and/or satellite receiver, wireless routers, heater, fan, ceiling fans, dehumidifier, electric filter, water bed heater, electric blanket, chair massager, electric massager, hair dryer, hair curler, electric shaver, exhaust fan, sprinkler system, pool heater, pool water filling systems, security system, outdoor water faucet, outdoor electric plug, outdoor lighting, water heater, bath tub, Jacuzzi, shower, shower head, sink, sink faucet, computer, Hot Spot water heater, air purifier, water purifier, ice maker, blender, food processor, disposal, compactor, light, fireplace, stereo, TV, toaster, stove, crock pot, electric frying pan, outdoor grill, boiler, dust buster, vacuum cleaner, printer, telephone, computer, game systems, AV equipment, network equipment, filtration systems, etc.] [Business and Industrial devices—oven, washing machine, dryer, central or window air conditioner, microwave, coffee maker, dishwasher, refrigerator, freezer, cable and/or satellite receiver, wireless routers, heater, fan, ceiling fan, dehumidifier, electric filter, exhaust fan, sprinkler system, pool heater, pool water filling systems, water park water supply, amusement park rides, security system, outdoor water faucet, outdoor electric plugs, outdoor lighting, water heater, shower, shower head, sink, sink faucet, computer, light, stereo, TV, toaster, stove, grill, boiler, vacuum cleaner, printer, telephone, computer, AV equipment, network equipment, filtration systems, robotic equipment, welding equipment, chemical processing equipment, manufacturing and/or industrial equipment, cooling systems, etc.] being monitored by the resource monitoring device in a business, residence or other location (e.g., home, condo, apartment, rental property, hotel, motel, factory, office complex, cruise ship, airplane, train, etc.); 3) a region in a business, residence or other location (e.g., house kitchen, house living room, first floor of house, certain apartment or group of apartments in an apartment complex, certain cabin on a ship, certain office or group of offices in an office complex, etc.) that the one or more monitored resource consuming devices are located; 4) the operation of one or more one or more monitored resource consuming devices with certain parameters (e.g., water consumption in office restroom per day within a certain amount, electricity consumption in house kitchen within a certain amount; etc.); and/or 5) the resource cost (e.g., average cost, cost during the peak use period, etc.) for use by the one or more resource consuming devices. As can be appreciated, the resource consuming devices that can be monitored by the resource monitoring device of the present invention is non-limiting. Essentially, any type of resource consuming device can be monitored the resource monitoring device of the present invention. As can be appreciated, the information obtained by the one or more resource monitoring devices can be used to a) create a resource budget or plan, b) allow a user to propose and/or implement changes in resource usage to fall with a resource consumption plan, c) allow a user to determine whether the resource plan is being followed or being deviated from, etc. As can be appreciated, the identity information of a particular resource consuming device can be automatically detected by the resource monitoring device, and/or manually inputted in the resource monitoring device. As can also be appreciated, the identity of the resource consuming device can be very specific, (e.g., Basement GE electric stove Model #00000, Kitchen Maytag dishwasher Model #00000, etc.), be specific (e.g., GE electric stove, Maytag dishwasher, etc.), be less specific (e.g., electric stove, dishwasher, etc.), or be even less specific (e.g., appliance, lights, etc.). The specificity of a particular resource consuming device is non-limiting. Non-limiting examples of information about the identity of the resource consuming device can include device type (e.g., oven, dishwasher, coffee maker, etc.), manufacturer, model number, serial number, warranty information, service contact information, date purchased, date installed, date of manufacture, location of home device located or installed, etc. As such, the resource monitoring device can be designed to provide as little or as much information about the identity of the resource consuming device as desired. As can be appreciated, the identity of the resource consuming device is not limited to a particular resource consuming device, but can include a particular or series of plugs or light switches (e.g., NE wall plug in family room, kitchen plugs, light switch for light over fireplace, switches for all family room lights, ceiling fan switch in master bedroom, all fan switches in house, etc.), can be associated with one or more circuit breakers (e.g., oven circuit breaker, central air circuit breaker, kitchen lights circuit breaker, dryer circuit breaker, main circuit breaker, etc.), can be associated with a particular water line (e.g., water line to water heater, water line to sprinkler, water line to dishwasher, etc.) and/or the main water line, and/or can be associated with a particular gas line (e.g., gas line to furnace, gas line to fireplace, etc.) and/or the main gas line.

In still another and/or alternative non-limiting aspect of the present invention, the resource monitoring device can be partially or fully incorporated in the resource consuming device. The partial or full incorporation of a resource monitoring device in a particular resource consuming device can be particularly made for the resource consuming device or be an option (e.g., model option, etc.) for a particular resource consuming device. Typically, when the resource monitoring device is partially or fully incorporated in the resource consuming device, the manufacturer incorporates such resource monitoring device on and/or into the resource consuming device; however, this is not required. When the resource monitoring device is partially or fully incorporated into the resource consuming device, the resource monitoring device can be designed to be fully accessible to a consumer, partially accessible to a consumer, or inaccessible to a consumer. If the resource monitoring device is made readily accessible to a consumer, one or more displays and/or buttons on the resource monitoring device and/or resource monitoring device can be accessible to the consumer. Alternatively or additionally, the resource consuming device can include a communication port (e.g., USB port, firewire port, etc.) and/or include a wireless connection to enable a user to connect and/or communicate with the resource monitoring device that is partially or fully incorporated in the resource consuming device.

In yet another and/or alternative non-limiting aspect of the present invention, the resource monitoring device can be connected in line with the resource consuming device. Such inline positioning of the resource monitoring device can be a modular or non-modular configuration for the resource monitoring device. Many different designs of the resource monitoring device can be used to place the resource monitoring device in line with the resource consuming device. For example, when the resource monitoring device is designed to measure electricity consumption by a resource consuming device, the resource monitoring device can be designed so that 1) the resource consuming device plugs into the resource monitoring device which in turn is plugged into an electric outlet, 2) the resource monitoring device is incorporated in an electric outlet wherein a resource consuming device is plugged therein, 3) the resource monitoring device is incorporated in a surge protector that is connected to an electric outlet wherein a resource consuming device is plugged therein, 4) the resource monitoring device is connected in line with an electric wire that is connected to an electric outlet wherein a resource consuming device is plugged therein, 5) the resource monitoring device is incorporated in a circuit breaker that supplies power to one or more plugs and/or regions of a residence, business and/or industrial facility and/or 6) the resource monitoring device is incorporated in an extension cord and/or power strip that supplies power to one or more resource consuming devices. In another example, when resource monitoring device is designed to measure natural gas consumption by a resource consuming device, the resource monitoring device can be designed so that 1) the natural gas supply for the resource consuming device is fluidly connected to the resource monitoring device which in turn is connected to a natural gas supply, 2) the resource monitoring device for one or more resource consuming devices is fluidly connected to the one or more resource consuming devices to measure and/or monitor natural gas consumption for a particular region of a residence, business and/or industrial facility (e.g., particular room of a residence, particular floor of a residence, a particular apartment in an apartment complex, a particle plant at a manufacturing facility, etc.). In still another example, when the resource monitoring device is designed to measure water consumption by a resource consuming device, the resource monitoring device can be designed so that 1) the water supply for the resource consuming device is fluidly connected to the resource monitoring device which in turn is connected to a water, 2) the resource monitoring device for one or more resource consuming devices is fluidly connected to the one or more resource consuming devices to measure and/or monitor water consumption for a particular region of a residence, business and/or industrial facility. As can be appreciated, the resource monitoring device can in connected in-line in other and/or additional ways. The size and/or configuration of the resource monitoring device are non-limiting. As can be appreciated from these non-limiting examples, other or additional resources can be monitored and/or measured by the resource monitoring device being connected in line with one or more resource consuming devices by similar and/or alternative arrangements. The use of the resource monitoring device of the present invention can be very beneficial for use in older apartments and other buildings wherein the electric wiring is not conducive to separating out usage for particular rooms and/or units. The use of the resource monitoring device can be used to easily monitor the resource usage of one or more resources for a particular unit and/or room thereby enabling the costs of such resource consumption to be directly passed to individual consumers instead of charging the consumers an average resource consumption cost. As mentioned above, the resource monitoring device has a modular or non-modular configuration. A non-limiting example of a modular configuration of a resource monitoring device for use in monitoring electricity consumption is disclosed in U.S. Patent Provisional Application Ser. Nos. 60/512,623 filed Oct. 20, 2003 and 61/153,050 filed Feb. 17, 209, which are both fully incorporated herein by reference. In this non-limiting design, the modular resource monitoring device is designed to be plug into an electric wall outlet or plug and the resource consuming device in turn is connected to the modular resource monitoring device. For purposes of this invention, a modular resource monitoring device is defined as a resource monitoring device that can be easily connected to a resource supply and a resource consuming device. For example, a resource monitoring device that can be plugged into a standard electrical outlet and also allow a resource consuming device to be plugged into the resource monitoring device would be considered a modular resource monitoring device for purposes of this invention. Likewise, a resource monitoring device that can be screwed into a standard light socket and also allow a resource consuming device such a light bulb to be screwed into the resource monitoring device would also be considered a modular resource monitoring device for purposes of this invention. However, a resource monitoring device that is located in a circuit breaker, an electric plug, a light switch, partially or fully incorporated in a resource consuming device, etc. is not considered a modular device for purposes of this invention. In a further example, a resource monitoring device that can be easily connected to a water faucet or hose and allows a resource consuming device (e.g., sprinkler, water purifier, etc.) to be connected to the resource monitoring device would be considered a modular resource monitoring device for purposes of this invention. However, a resource monitoring device that requires connection to a water source shower, bathtub, main water line, etc. would not considered a modular resource monitoring device for purposes of this invention. Similar examples can be applied to a natural gas source.

In still yet another and/or alternative non-limiting aspect of the present invention, the resource monitoring device is a modular device for monitoring electrical energy. The modular resource monitoring device can be designed to monitor, record, transmit, etc. information regarding the electrical energy being consumed by a resource consuming device as electricity flows through the modular resource monitoring device. The information monitored, recorded, transmitted, etc. by the modular resource monitoring device can include one or more types of information (e.g., total kilowatt hours of power consumed, the amount of power consumed during a particular time period, the peak power consumption, the average power consumption over a period of time, time period the resource consuming device consumed power, the actual and/or estimated cost of power consumed by the resource consuming device, the cost of electric power at a particular time period, the cost of power used during a particular time period, etc.). The size of the modular resource monitoring device is not limited. The modular resource monitoring device can be designed to support multiple voltage levels and/or plug types; however, this is not required. The voltage level setting for the modular resource monitoring device, when used, can be manual and/or automatic; however, this is not required. The body of the modular resource monitoring device can be made of any number of materials (e.g., metal, plastic, fiberglass, etc.). The modular resource monitoring device can have any type of color, shape and/or design. The modular resource monitoring device can include more than one plug so that more than one resource consuming device can be connected to the monitoring device; however, this is not required. If the modular resource monitoring device includes more than one plug, the modular resource monitoring device can be designed to provide information about the amount of energy consumption for each plug, information about each of the resource consuming devices connected to each plug, etc.; however, this is not required. When the modular resource monitoring device more than plug, the resource monitoring device in the modular device can be designed to include single and/or separate memory locations for the resource consuming devices plugged into the modular resource monitoring device so that information on each resource consuming device and/or one or more combinations of the resource consuming devices can be displayed, stored and/or reported; however, this is not required. The modular resource monitoring device can include electronics to identify and/or distinguish the resource consumption by one or more resource consuming devices; however, this is not required. The modular device can include a circuit breaker; however, this is not required. The modular device will be typically UL listed and/or include any other appropriate electrical approvals. The modular device can be designed to be water resistant for outdoor use; however, this is not required. The increments of information that are measured, displayed and/or reported by the modular resource monitoring device can be set at any desired and/or practical increment. The accuracy of the modular resource monitoring device can also be set at any desired and/or practical amount. The modular resource monitoring device can include one or more displays that are lighted and/or backlit; however, this is not required. The modular resource monitoring device can include one or more control knobs or buttons to toggle between various attributes and memory locations of the modular device; however, this is not required. The modular resource monitoring device can be powered by an independent power source such as a battery and/or be powered by the electricity from an electrical outlet. The modular device can include a wire connection or a cable connection (e.g., Ethernet connection, USB connection, fire wire connection, etc.) and/or a wireless connection to enable a user to connect the resource monitoring device to another electronic device (e.g., desktop computer, laptop computer, tablet, IPad, ITouch, mobile phone, blackberry, etc.) to enable a user, to receive information from and/or input information into the resource monitoring device; however, this is not required. As can be appreciated, the modular resource monitoring device can include additional and/or alternative features. As can also be appreciated, some or all of the features and/or functions of the modular resource monitoring device for use with electricity consuming devices as described above can be in resource monitoring device that are not in a modular form (e.g., resource monitoring device incorporated into an electric plug, resource monitoring device incorporated into a fan or light switch, resource monitoring device incorporated in a circuit breaker for a circuit breaker box, resource monitoring device partially or fully incorporated into a resource consuming device, etc.), or in a resource monitoring device in a modular or non-modular form that is used to monitor resources other than or in addition to electrical power consumption.

In still another and/or alternative aspect of the present invention, the resource monitoring device can be designed to be connected to a power cord of an electricity consuming device. In one non-limiting design, the resource monitoring device is designed to be clamped onto an existing power cord. A user can simply place the resource monitoring device on a portion of the power cord and then push together, tighten, etc. a portion of the resource monitoring device to cause the resource monitoring device to be clamped to the power cord and penetrate the other layer of the power cord so that the electric wiring in the power cord is at least partially engaged by one or more electric contacts of the resource monitoring device. In another non-limiting design, the resource monitoring device is designed to be connected to a power cord after a user cuts the power cord. On end of the cut power cord is connected to one portion of the resource monitoring device and the other cut end is connected to another portion of the resource monitoring device. In still another non-limiting design, the resource monitoring device is pre-installed or incorporated into a power cord. In this non-limiting design, the user substitutes the original power cord of a device with the power cord that includes the pre-installed or incorporated resource monitoring device.

In another and/or alternative aspect of the present invention, the resource monitoring device can include one or more storage media to permanently or temporarily retained one or more types of information over a particular period of time. Such storage media can include a hard disk, memory stick, flash memory chips, etc. The storage media can be designed to be removable from the resource monitoring device and/or be permanently affixed to the resource monitoring device. The resource monitoring device can include one or more arrangements designed to transfer and/or receive information (e.g., floppy disk reader/writer, CD reader/writer, DVD reader/writer, memory stick reader/writer, fire wire connector, IR transmitter, RF transmitter, laser light transmitter, microwave transmitter, memory stick connector, phone line connector, computer cable connector, Ethernet connector, electric wire connector, fiber optic cable connector, USB cable connector, coaxial cable connector, various types of information transmission cables, etc.).

In still another and/or alternative aspect of the present invention, the resource monitoring device can include an Energy Star compliant indicator and/or transmit information to a remote monitoring location to provide a user at the remote monitoring location information about the Energy Star compliance of a resource consuming device. In one non-limiting design, the resource monitoring device can produce a visual and/or audible signal to inform a user whether a resource consuming device is Energy Star compliant. The visual signal can include one or more lights on the resource monitoring device, and/or a resource monitoring device that has a display panel or screen that provides a user with information about the Energy Star compliance of a resource consuming device. In one non-limiting configuration, the resource monitoring device can inform a user that resource consuming device is a) Energy Star compliant (e.g., green light, display that states Energy Star compliant, etc.), b) borderline or almost Energy Star compliant (e.g., yellow light, display that states marginal or almost Energy Star compliant, etc.), and/or c) not Energy Star compliant (e.g., red light, display that states not Energy Star compliant, etc.). In another and/or alternative non-limiting configuration, the resource monitoring device can transmit information to one or more remote monitoring locations to provide a user at the one or more remote monitoring locations information about the Energy Star compliance of a particular resource consuming device. In still another and/or alternative non-limiting configuration, the resource monitoring device can produce an audible sound when the resource consuming device is Energy Star compliant, borderline or almost Energy Star compliant, and/or not Energy Star compliant. The sound for different states of Energy Star compliance can be the same or different. The resource monitoring device can be designed to only produce an audible sound when the resource consuming device is in a certain state of Energy Star compliance (e.g., borderline or almost Energy Star compliant, not Energy Star compliant, etc.). The visual and/or audible signals and/or information transmitted to one or more remote monitoring locations can be used by a user to a) rate the efficiency of a resource consuming device, b) monitor the deterioration of a resource consuming device, and/or c) identify a broken or defective resource consuming device. In another and/or alternative non-limiting design, the resource monitoring device can be programmed by a user (e.g., input information via display panel, input information via remote monitoring location, input information via wirelessly and/or through a cable connection. etc.) to identify a certain resource consuming device being monitored by the resource monitoring device so that the resource monitoring device can provide more accurate information to the user regarding 1) the Energy Star compliance of the resource consuming device and/or 2) the proper and/or improper resource consumption by the resource consuming device.

In still another and/or alternative aspect of the present invention, one or more resource monitoring devices can be designed to directly and/or indirectly provide information to, and/or receive information from one or more central data processing and/or storage facilities (e.g., desktop computer, laptop computer, tablet computer, [Pad, PDA, Palm Pilot, Internet, proprietary computer bank, proprietary data base, etc.). In one non-limiting embodiment of the invention, the information transferred to the one or more central data processing and/or storage facilities, and/or data being transferred from the one or more central data storage and/or processing facilities can be continuous feed, periodic feed, and/or be manually inputted. In another and/or alternative non-limiting embodiment of the invention, the data that is downloaded into the one or more central data processing and/or storage facilities can include one or more software programs to enable an operator to monitor various resource consumption parameters obtained from one or more resource monitoring devices. The one or more software programs can be used to provide graphs, charts, tables, and/or the like used generate information on the resource consumption of one or more resource consuming devices that are integrated, connected and/or interconnected with one or more resource monitoring devices. This data can also and/or alternatively be used by the consumer and/or third party to monitor, estimate and/or project the cost of operating one or more resource consuming devices. This information can be used to assist a consumer and/or third party in obtaining cost information and/or estimated cost information on the operation and/or use of one or more resource consuming devices. The information obtained can also and/or alternatively be used by a consumer and/or third party to modify the amount and/or time of use of one or more resource consuming devices. This information can also and/or alternatively be used to reduce the energy costs associated with the operation of one or more resource consuming devices. In still another and/or alternative embodiment of the invention, the one or more software programs used to process the information downloaded and/or received from one or more resource monitoring devices can be used to provide historical information on one or more parameters associated with one or more energy consuming devices. This information could be used to inform and/or notify the consumer and/or third party that an inordinate amount of usage (e.g., too much, too little, use at improper times, etc.) of one or more resource consuming devices has occurred (e.g. water leak, gas leak, filter needs to be changed, device broken, etc.). The information could then be used to repair and/or adjust a resource consuming device as required. The information can also or alternatively be used to activate a warning signal or alarm to inform a user that a resource consuming device is a) burning out or failing to enable a user to take corrective action (e.g., appliance beginning to fail or has failed so buy new appliance, etc.) and/or b) non-standard resource usage by a resource consuming device (e.g., too much electricity being used so turn off lights, turn off over/stove and/or other appliance, turn off air conditioner/heater, turn off fan, etc.; water running too long so check for leak, turn off faucet, turn off commode, turn off washer, turn off dishwasher, turn off pool water supply, etc.; too must gas being use so check for leak, turn off fireplace, turn off furnace, turn off water heater, turn off gas over/stove, turn off gas dryer, etc.). In yet another and/or alternative embodiment of the invention, the one or more software programs used to process the information downloaded and/or received from one or more resource monitoring devices can be used to a) notify a consumer and/or third party of information about the resource consuming device, b) notify a consumer and/or third party of information about setting and/or operational information about one or more resource consuming devices, c) enable a consumer and/or third party to modify and/or control one or more resource monitoring devices, d) enable a consumer and/or third party to modify and/or control one or more resource consuming devices integrated with, connected to, and/or interconnected to one or more resource monitoring devices, e) automatically modify and/or control one or more resource monitoring devices, and/or f) automatically modify and/or control one or more resource consuming devices integrated with, connected to, and/or interconnected to one or more resource monitoring devices. In still yet another and/or alternative embodiment of the invention, the one or more software programs can be used to send and/or provide data to one or more resource monitoring devices to cause a dump of one or more pieces of information from the one or more resource monitoring devices to the one or more central data processing and/or storage facilities, and/or to provide other and/or additional information to one or more one or more resource monitoring devices (e.g., time, day, year, updated resource cost, updated use information, etc.). The sending and/or the receiving of information between one or more resource monitoring devices and one or more central data processing and/or storage facilities also can be used to a) provide information on the proper operation of the one or more resource monitoring devices and/or one or more central data processing and/or storage devices, and/or b) verify data transfer and/or accuracy of transferred data. The transfer of information between one or more resource monitoring devices and/or one or more central data processing and/or storage facilities can be automatic and/or manually instituted. The transferred information can occur continuously, at discreet periods of time, and/or after one or more triggering events have occurred (e.g., power outage, power surge, activation and/or deactivation of one or more circuit breakers, manual command by an operator, etc.). The information used by the one or more software programs can be manually inputted, and/or downloaded from one or more sources.

In yet another and/or alternative aspect of the present invention, the information from one or more resource monitoring devices can be used to provide actual and/or estimated resource cost information associated with the actual and/or planned operating of one or more resource consuming devices over a period of time. A software program can be incorporated in one or more resource monitoring devices and/or one or more central data processing and/or storage facilities to calculate these actual and/or anticipated costs. The resource rates for a particular locale can be provided by a private service, downloaded from the internet, downloaded from a modem, manually inputted, etc. These rates can then be used to calculate the resource cost analysis. These rates and/or additional information can be provided automatically and/or manually to one or more resource monitoring devices and/or one or more central data processing and/or storage facilities. The one or more software programs can be designed to automatically provide and/or provide when prompted, generated information about one or more resource monitoring devices, one or more individual resource consuming devices and/or one or more resource consuming devices integrated with, connected to and/or interconnected with one or more resource monitoring devices. This generated information can take a variety of different fowls (preformed templates, custom templates, etc.). This generated information can be used to 1) identify underperforming resource consuming devices, 2) suggested more energy efficient resource consuming devices to replace existing resource consuming devices, 3) suggest operation times and/or operating parameters for one or more resource consuming devices, 4) provide product information about one or more resource consuming devices, 5) provide information about new products related to one or more energy consuming devices, 6) provide information about one or more products related to one or more resource consuming devices, and/or other and/or additional information.

In a further and/or alternative aspect of the present invention, the information from one or more resource monitoring devices can be used to control the operation of one or more resource consuming devices based on one or more parameters (e.g., cost of operation, amount of operation, period of operation, when user is at or away from a location of the resource consuming device, the awake and sleep periods of a user at the location of the resource consuming device, the time of year, etc.). As a result, the life of one or more resource consuming devices can be modified and/or the cost of operating one or more resource consuming devices can be controlled. The control of operation of the one or more resource consuming devices can be done manually (e.g., user turns or turns off resource consuming devices based on a schedule that was created from information monitored by one or more resource monitoring devices, user changes a thermostat based on a schedule that was created from information monitored by one or more resource monitoring devices, user only uses the dryer based on a schedule that was created from information monitored by one or more resource monitoring devices, etc.) and/or automatically. Automatic control of one or more resource consuming devices can be obtained by sending control information directly to the resource consuming devices and/or by controlling the operation of the resource consuming devices by controlling one or more resource monitoring devices (e.g., continuously or periodically controlling water flow through one or more resource monitoring devices, continuously or periodically controlling natural gas flow through one or more resource monitoring devices, continuously or periodically controlling current flow through one or more resource monitoring devices, etc.).

In still a further and/or alternative aspect of the present invention, the information acquired by one or more resource monitoring devices and/or one or more central data processing and/or storage devices can be provided free or a user or can be provided at a cost to the user by one or more private services (e.g., energy management service, etc.). Such private service can be used to provide a variety of information to the user (e.g., recommendations on the time and/or amount of energy consumption for a particular resource consuming device, the operating parameters for a particular resource consuming device, recommendations for replacing a particular resource consuming device with a more efficient energy consuming device, etc.). The private service can be used to provide other and/or additional services related to one or more resource consuming devices (e.g., resource rate information; product rebates; pricing information on various resource consuming devices; pricing information on various resource providers and/or information about such providers; recommenced maintenance information and/or maintenance scheduling information for a resource consuming device; ratings and/or reviews concerning various resource consuming devices; software downloads and/or updates for software used one or more resource monitoring devices and/or one or more central data processing and/or storage devices; recall information concerning various resource consuming devices; service information and/or services to setup, repair and/or maintain the resource monitoring devices and/or resource consuming devices; laws, regulations, proposed rules, public notices, proposed regulations and/or legislation, and/or city ordinances related to various resource consuming devices; etc.).

In yet a further and/or alternative aspect of the present invention, there is provided a resource monitoring system that can be at least partially professionally installed, at least partially installed by a manufacturer of a product (e.g. Maytag, Whirlpool, G.E., etc.) and/or at least partially installed by installed by individual consumers to enable a business, consumer and/or third party to monitor the resource consumption by one or more resource consuming devices. The resource monitoring devices can be incorporated in one or more resource consuming devices, interconnected with one or more resource consuming devices, and/or can be connected in line with one or more resource consuming devices. In one non-limiting example, manufacturers of larger resource consuming devices (e.g., dishwasher, washing machine, dryer, refrigerator, oven, stove, water heater, heater, air conditioner, furnace, gas fireplace equipment, water softener, stereo equipment, A-V equipment, TV, computer equipment, etc.) and/or higher end models of resource consuming devices would partially or fully incorporate the resource monitoring device in the manufactured device appliance.

In another and/or alternative aspect of the present invention, there is provided a resource monitoring system for monitoring electrical energy that has a modular design that can be used with resource consuming devices that may or may have a resource monitoring device that is partially or fully incorporated in the resource consuming device. For example, the resource consumption of smaller resource consuming devices (e.g., toaster, cordless phone, microwave, small appliances, hair dryer, answering machine, etc.) and/or appliances and/or equipment that do not incorporate a resource monitoring device can be connected or interconnected to a modular resource monitoring device. For example, one or more resource consuming devices can be connected to a modular resource monitoring device such as modular resource monitoring device that includes one or more outlets designed to receive the plug of one or more resource consuming devices. In one non-limiting design, the modular resource monitoring device can have the form of a power strip having one or more outlets and a plug that plugs into a standard wall plug. In another non-limiting design, the modular resource monitoring device is a small compact device that has one or more outlets and a plug that plugs into a standard wall plug. In still another non-limiting design, the modular resource monitoring device is incorporated into a surge protector that has one or more outlets and a plug that plugs into a standard wall plug. In yet another non-limiting design, the modular resource monitoring device is incorporated into an extension cord or power cord that has one or more outlets and a plug that plugs into a standard wall plug. These types of resource monitoring devices are typically used with electric powered resource consuming devices. The modular resource monitoring device in this particular configuration can be movable to various electric outlets; however, this is not required. In another example, one or more resource consuming devices can be connected to a modular resource monitoring device such as modular resource monitoring device that can be screwed into a light socket and which modular resource monitoring device is designed to receive the threaded end of one or more resource consuming devices (e.g., a light bulb, etc.). Such a configuration is typically used for electric powered resource consuming devices. The modular resource monitoring device in this particular configuration can be movable to various light sockets; however, this is not required.

In still another and/or alternative aspect of the present invention, there is provided a resource monitoring device for monitoring electrical energy that has a non-modular design. When the resource monitoring device is a non-modular device, the non-modular configuration is not typically moved to other locations one installed or is not designed to be moved once installed. One non-limiting example of a non-modular resource monitoring device is a circuit breaker that includes a resource monitoring arrangement. The circuit breaker is designed to be inserted into the main or a secondary circuit breaker box of a house, business, etc. The circuit breaker cannot be used in other locations of the house, business, etc. Another non-limiting example of a non-modular resource monitoring device is a light switch that includes a resource monitoring arrangement. Although a light switch for a light, fan, fireplace, etc. can be relocated in other location, the moving of a light switch requires the disconnection and re-connection of electrical wires, thus for purposes of this invention, the requirement to disconnect and reconnect electric wires causes the device to be a non-modular device. As such, a resource monitoring arrangement that is incorporated in a wall plug is also considered a non-modular device for purposes of this invention. Still another non-limiting example of a non-modular resource monitoring device is device that is placed inside the wall of a house, business, etc., thus is difficult to access. For example, a device that is connected in-line with an electric line within a wall that is designed to monitor electrically passing through the line (e.g., an electric line to the electric dryer, an electric line to the central AC unit, etc.) is an example of non-modular resource monitoring device for purposes of the present invention.

In yet another and/or alternative aspect of the present invention there is provided a resource monitoring device for monitoring fluids (e.g., water, natural gas, propane, kerosene, fuel oil, gasoline, diesel fuel, hydrogen gas, liquid nitrogen, compressed gas, etc.) that has a modular design. The resource monitoring device is typically fluidly connected to the resource consuming device (e.g., gas water heater, gas furnace, gas dryer, nitrogen cooling system for a computer, washing machine, dishwasher, toilet, sink, bath tub, shower, outside water faucet, sprinkler system, hose, etc.); however, it can be appreciated that the resource monitoring device can also or alternatively be connected to a main source line (e.g., main water line, main gas line) and/or to a major line that supplies a resource to one or more locations (e.g., water line to basement, water line to first floor, gas line to the two furnaces, gas line to the two fireplaces, etc.). For purposes of the present invention, a modular resource monitoring device for a fluid resource consuming device is a device that can be easily connected to a fluid source. Non-limiting examples of an easy connection would be a device that can be screwed onto a fluid source such as an outside or garage water faucet, water source for a washing machine, etc. and the fluid resource consuming device can then be screwed into the resource monitoring device. A non-limiting example of uneasy connection would be a connection wherein special connectors are required (e.g., water source connectors for a sink, water source connectors for water heater, water source connectors for a dishwasher, gas source for water heater, gas source for furnace, etc.). Such uneasy connections generally require the pipe or tube of the resource to be cut, solder, weld, sealant tape or outer types of sealants other than a standard washer to seal the fluid line, the fluid line is embedded in a wall, etc. For purposes of this invention, fluid resource consuming device that connects to an uneasy connection is not a modular resource monitoring device. As can be appreciated, one or more of the non-limiting examples of uneasy connections may be easy connections for some types of fluid resource consuming devices.

In still yet another and/or alternative aspect of the present invention, once the one or more resource monitoring devices have been installed and/or the one or more resource consuming devices that at least partially incorporate a resource monitoring device have been purchased, the information concerning a resource consumed by one or more resource consuming devices can be displayed by the one or more resource monitoring devices and/or can be fed to one or more remote monitoring locations. When the resource monitoring device is designed to display information to a user, the displayed information can be basic information (e.g., indicator that indicates device operating, etc.) or more detail information (e.g., date, time, amount of resource used, time or operation of resource consuming device, state of Energy Star compliance, etc.). Different models of resource monitoring devices can be different amounts of displayed information. The resource monitoring device can be designed and/or be programmable to display as much information as desired. For instance, the resource monitoring device can be programmable to enable a user to input information regarding one or more information types (e.g., type of said resource consuming device [refrigerator, oven, wall plug, switch, circuit breaker, etc.], location of the resource consuming device [e.g., garage, basement, living room apartment 4A, etc.], model of the resource consuming device, date information, time information, resource rate information, Energy Star information about the resource consuming device, operating times of the resource consuming device, proper operating parameters of the resource consuming device, etc.). The resource monitoring device programmable by one or more arrangements such as, but not limited to, connecting an information or database to the resource monitoring device (e.g., flash drive, memory card, etc.), manual programming of the resource monitoring device (e.g., user input on a display of resource monitoring device, selection of buttons on resource monitoring device, etc.), and/or remote programming of the resource monitoring device by enter information at one or more remote monitoring locations and have such information transmitted to the resource monitoring device. When information is to be fed from one or more resource monitoring devices to one or more remote monitoring locations, the information can be fed wirelessly, by wire and/or cable, manually downloaded from a resource monitoring device and then uploaded to one or more central monitoring locations, and/or manually inputted. In one non-limiting arrangement, information from and/or to one or more resource monitoring devices is fed wirelessly and/or by wire and/or cable to one or more remote monitoring locations (e.g., desktop computer, laptop computer, server, etc.) wherein the received data can be stored and/or processed by one or more software programs to provide various types of information (e.g., real time resource usage information, periodic resource usage information, historical resource usage information, projected resource usage information, resource usage cost, historical resource usage cost, projected resource usage cost, Energy Star compliance, proper/improper resource consumption, etc.). In one non-limiting arrangement, information to and/or from one or more resource monitoring devices can be transmitted via the existing electrical wires of a house or building. In such an arrangement, a signal transmitted at a special frequency can be sent via the existing wiring of a home, thus no additional wiring is required to connect one or more resource monitoring devices to a one or more remote monitoring locations. Special security protocols can be used to verify signals sent between the one or more resource monitoring devices and/or the one or more remote monitoring locations. One or more software programs that are located in the one or more resource monitoring devices and/or the one or more remote monitoring locations can be used to provide resource consumption information of the single and/or multiple resource consuming devices. The resource monitoring system (e.g., resource monitoring device, remote monitoring location, etc.) can be packaged with additional services and/or additional services can later be obtained for use with the resource monitoring system. Such services can include, but are not limited to, resource cost information, Energy Star compliance, information on various resource consuming devices, information on laws and/or regulations that pertain to a consumable resource and/or resource consuming device, suggestions for future purchase of resource consuming devices, software updates, etc.

In another and/or alternative aspect of the present invention, there is provided a resource monitoring system that can be used in a pre-existing building and which requires little, if any additional wiring. In many preexisting structures, it can be difficult, expense and/or undesirable to install wiring to connect multiple resource monitoring devices in various locations in a structure so that such resource monitoring devices can be connected with and/or communication with a remote resource monitoring location. In one non-limiting embodiment, one or more resource monitoring devices include wireless communication (e.g., Bluetooth, RF, IEEE 802.11, etc.) to enable one or more resource monitoring device to communication with one another and/or with one or more remote monitoring locations. In such an arrangement, non-professional installation can be done by a user to create a basic, intermediate or advance resource monitoring system in a structure without need for expense and time consuming wiring in the structure. In another and/or alternative arrangement, one or more resource consuming devices can be plugged into a standard plug or screwed into a standard light socket and can use the wiring for the plug, light socket, etc. as a communication line between one or more resource monitoring devices and/or one or more remote monitoring locations. In such an arrangement, additional wiring in a structure would not be required to create a basic, intermediate or advanced resource monitoring system. A special communication device may be required to connect to the electrical system of a structure to differentiate signal from one or more resource monitoring devices and standard noise in the electrical system. Special electronics may also be required in the resource monitoring device to correctly identify signals between two or more resource monitoring devices and/or one or more remote resource monitoring locations.

In still another and/or alternative aspect of the present invention, there is provided a resource monitoring system that includes one or more non-modular resource monitoring devices such as one or more modified circuit breakers that are designed to be inserted in a circuit breaker box for a structure. The modified circuit breaker can include wireless communication, wire or cable connections and/or use the existing electric wiring in the structure to communicate with one or more resource monitoring devices.

It is one non-limiting object of the present invention to provide a resource monitoring system that can provide information on and/or related to the resource consumption of one or more resource consuming devices.

It is another and/or additional non-limiting object of the present invention to provide a resource monitoring system that includes one or more modular resource monitoring devices.

It is still another and/or additional non-limiting object of the present invention to provide a resource monitoring system that includes one or more non-modular resource monitoring devices.

It is yet another and/or additional non-limiting object of the present invention to provide a resource monitoring system that includes one or more resource monitoring devices that communicate with one or more remote resource monitoring locations.

These and other objects of the invention will become apparent to those skilled in the art upon reading and understanding the following detailed description of preferred embodiments taken together with the drawings.

### BRIEF DESCRIPTION OF THE DRAWINGS

Reference may now be made to the drawings, which illustrate several non-limiting embodiments that the invention may take in physical form and in certain parts and arrangements of parts wherein;

FIGS. 1A and 1B illustrate a non-limiting modular resource monitoring device;

FIGS. 2A and 2B illustrate another non-limiting modular resource monitoring device;

FIG. 3 illustrates a refrigerator that includes a resource monitoring device incorporated in the refrigerator;

FIG. 4 illustrates a non-limiting non-modular resource monitoring device that is incorporated in a circuit breaker;

FIG. 5 illustrates a non-limiting resource monitoring system in accordance with the present invention;

FIG. 6 illustrates the monitoring of resource consuming device through the existing electric wiring of a structure; and,

FIG. 7 illustrates a non-limiting display from a computer of a resource monitoring system.

### NON-LIMITING EMBODIMENTS OF THE INVENTION

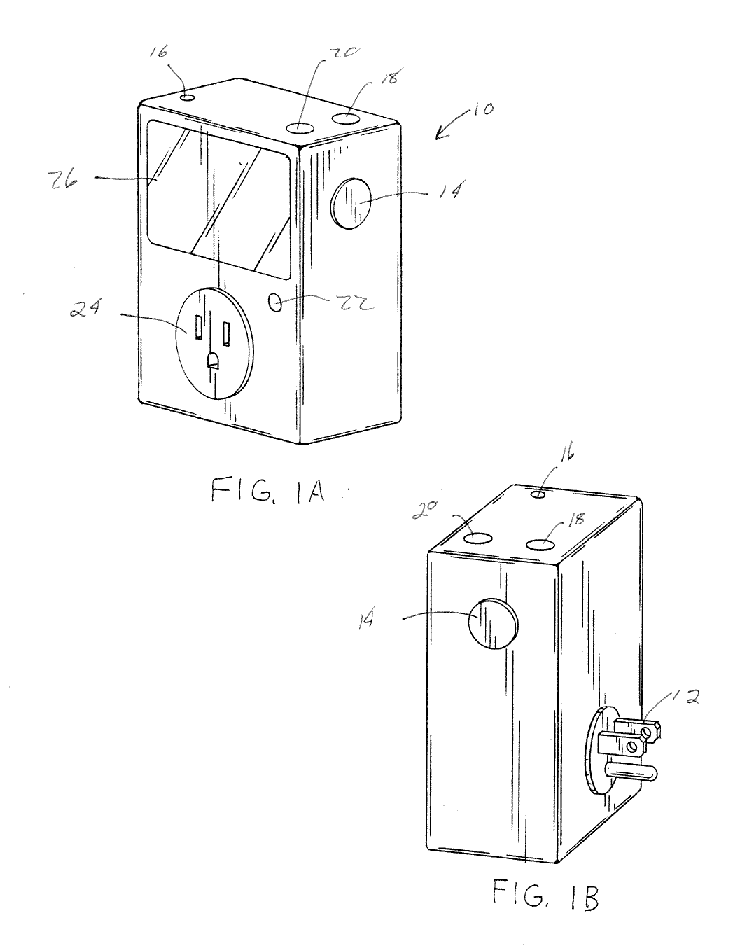

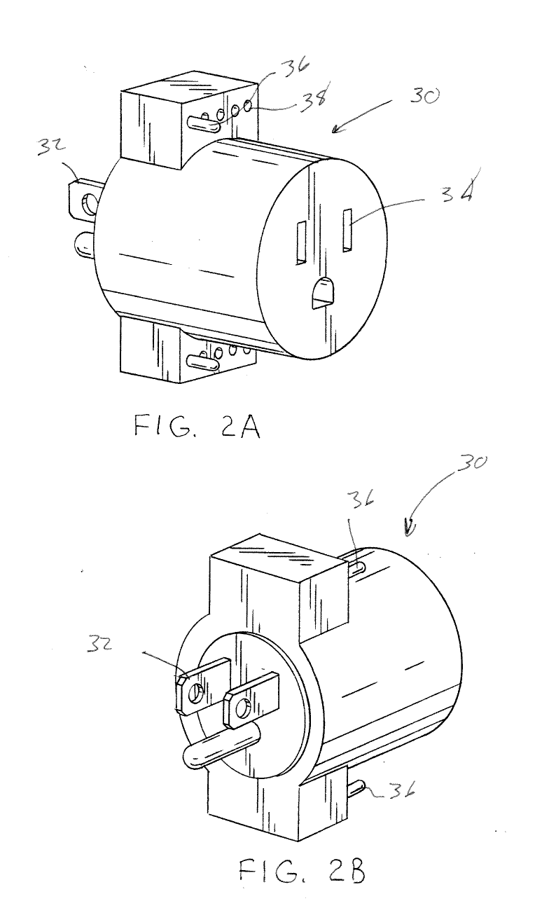

Referring now to the drawings wherein the showings are for the purpose of illustrating non-limiting embodiments of the invention only and not for the purpose of limiting same, FIGS. 1 and 2 illustrate two non-limiting configurations of a modular resource monitoring devices 10, 30 in accordance with the present invention. As illustrated in FIG. 1, resource monitoring device 10 is a generally small unit (e.g., wall timer, etc.). The size of the resource monitoring device is non-limiting. The resource monitoring device includes a plug 12 that is designed to be inserted in a standard wall outlet. Plug 12 is generally used to power the components in the resource monitoring device; however, the resource monitoring device can include a battery power supply or some other alternate power supply; however, this is not required. As illustrated in FIG. 1, the resource monitoring device includes a battery cover 14 that can be removed to insert or remove a battery from the resource monitoring device. The resource monitoring device also includes one or more buttons 16, 18, 20, 22 that enables a user to access information from the resource monitoring device and/or to program the resource monitoring device. The display can be a touch display that can also or alternatively be used to access and/or program and/or configure one or more features of the resource monitoring device. The resource monitoring device also includes a plug receptacle 24 that enables an electric resource consuming device to be plugged into the resource monitoring device. The resource monitoring device can include more than one plug receptacle 24; however, this is not required. The resource monitoring device also includes a display 26 that can be used to view one or more features of the resource monitoring device (e.g., energy consumption, time of use, estimate cost of use, etc.) and/or to enable a user to program and/or modify one or more features of the resource monitoring device (e.g., setup wireless communication, setup time and date, input information about resource monitoring device, connect device to one or more other devices and/or one or more remote monitoring locations, etc.).

FIG. 2 illustrates another modular resource monitoring device 30. This modular device includes a plug 32 and plug receptacle 34. The modular resource monitoring device is a similar configuration in that the modular resource monitoring device does not include a display. The modular resource monitoring device includes a removable pin 36 that can be inserted into one or more pin holes 38. The pins can be used to program the modular resource monitoring device, activate/deactivate one or more features of the modular resource monitoring device, and/or keep track of time, etc.

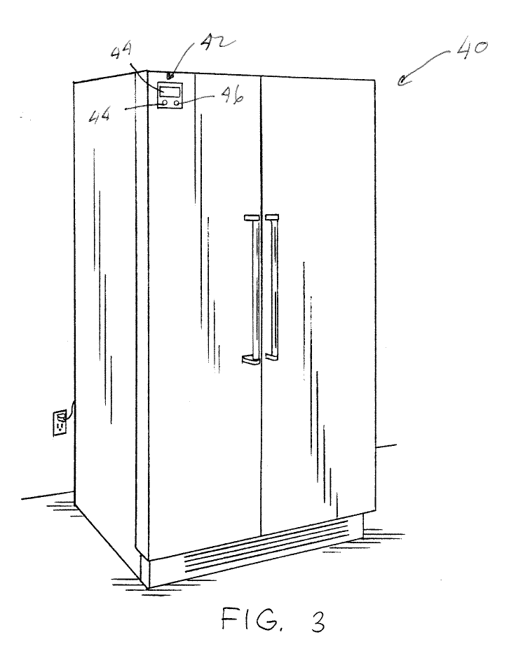

The resource monitoring device is not limited to a modular resource monitoring device. As illustrated in FIG. 3, the resource monitoring device is incorporated in a refrigerator 40. A panel 42 is incorporated in the refrigerator that allows the use to access the resource monitoring device. The resource monitoring device includes a display panel 44 and two user buttons 46, 48. As can be appreciated, the resource monitoring device can include more or less displays and/or buttons. The one or more buttons enable a user to access information from the resource monitoring device and/or to program and/or to configure the resource monitoring device. The display can be a touch display that can also or alternatively be used to access and/or program and/or configure one or more features of the resource monitoring device. The resource monitoring device is a non-modular resource monitoring device since it is incorporated into the refrigerator.

As can be appreciated, when refrigerator 40 or any other electric appliance or electricity consuming device does not include a resource monitoring device, the resource monitoring device illustrated in FIGS. 1 and 2 can be used with refrigerator 40 or any other electric appliance or electricity consuming device.

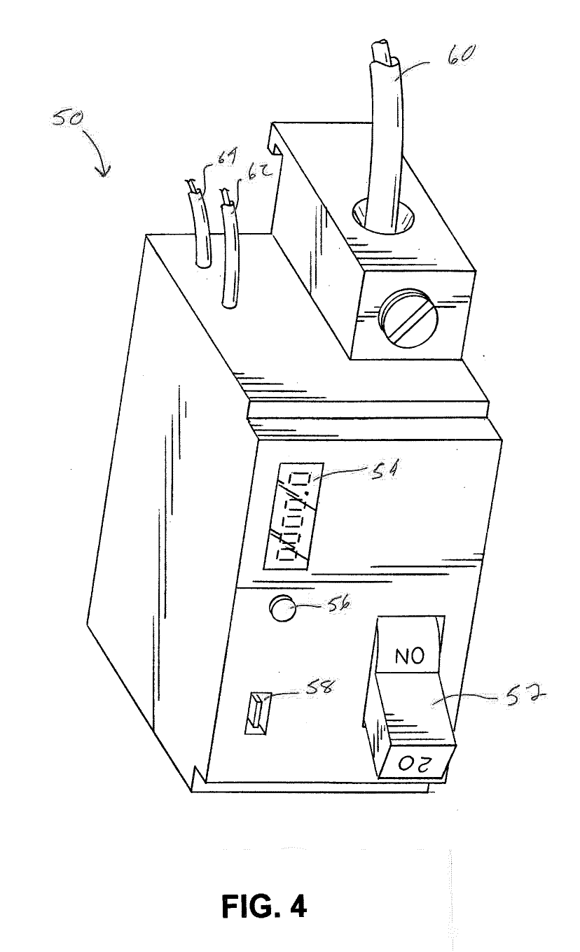

Referring now to FIG. 4, there is illustrated a circuit breaker that is designed to be inserted in a circuit breaker box 50. The circuit breaker includes a breaker switch 52, a display 54, a user button 56, and a communication port 58. Wires 60, 62, 64 are connected to the circuit breaker. The display can be used to display any type of information desired by the user. The one or more buttons enable a user to access information from the resource monitoring device and/or to program and/or to configure the resource monitoring device. The display can be a touch display that can also or alternatively be used to access and/or program and/or configure one or more features of the resource monitoring device. The communication port can be used to connect the resource monitoring to one or more other resource monitoring devices and/or one or more remote monitoring locations (e.g., computer, cellular phone, Ipod, interne, etc.). As can be appreciated, the resource monitoring devices disclosed in FIGS. 1-3 may also include one or more communication ports; however, this is not required.

As can be appreciated, the shape of the resource monitoring devices illustrated in FIGS. 1-4 is non-limiting. Also, the number of buttons, displays, and communication ports on the resource monitoring devices illustrated in FIGS. 1-4 is non-limiting. The resource monitoring devices illustrated in FIGS. 1-4 can include wireless communication for connecting to one or more other resource monitoring devices and/or one or more remote monitoring locations; however, this is not required. The resource monitoring devices illustrated in FIGS. 1-4 can include one or more wire or cable communications for connecting to one or more other resource monitoring devices and/or one or more remote monitoring locations; however, this is not required. The resource monitoring devices illustrated in FIGS. 1-4 can include electronics to connect with one or more other resource monitoring devices and/or one or more remote monitoring locations via the existing wiring of a structure; however, this is not required. When the resource monitoring device has more than one plug receptacles, the resource monitoring device can include electronics to differentiate between the resources consumed through each of the plug receptacles; however, this is not required.

The resource monitoring devices illustrated in FIGS. 1-4 are for electricity consuming devices. As can be appreciated, the resource monitoring devices can be designed for fluid resource monitoring. In such a design, the plug and plug receptacles can be substituted for a threaded opening that can accept a standard hose or other threaded connection. The features of the fluid resource monitoring device can be similar to the features discussed above with regard to the resource monitoring device for electricity consuming devices.

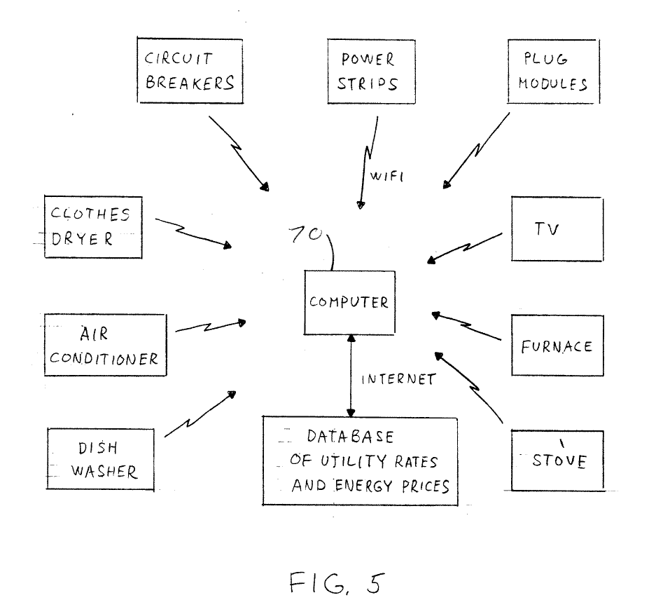

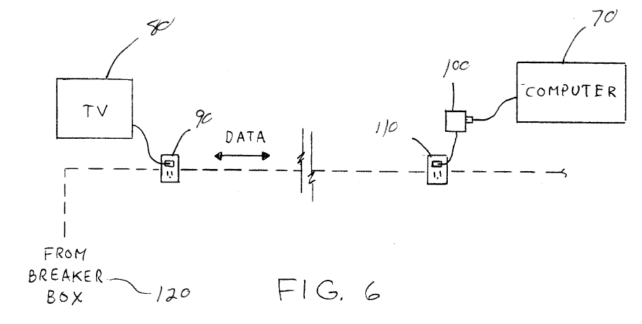

Referring now to FIGS. 5 and 6, the resource monitoring system can be deigned to be connected wirelessly with one or more resource monitoring devices that are monitoring one or more resource consuming devices. As illustrated in FIG. 5, a plurality of resource monitoring devices is being used to monitor resource consumption from devices in a structure such as a home. Several non-limiting resource consuming devices are illustrated such as one or more TVs, a furnace, a stove, a dishwasher, an air conditioner, and a clothes dryer. The furnace and/or stove may consume only electricity or may consume both electricity and a fluid such as natural gas, propane, kerosene, etc. If the furnace only includes electricity, then a single resource consuming device can be used. If the furnace and/or stove consume both electricity and a fluid, then two or more resource consuming devices can be used to monitor the resources being consumed by the furnace and/or stove. The dishwasher typically consumes both electricity and water. As such, two or more resource consuming devices can be used to monitor the resources being consumed by the dishwasher. The air conditioner and/or furnace may include a humidifier. As such, an additional resource consuming devices can be used to monitor the resources being consumed by the humidifier. The clothes dryer may use electricity and/or gas. As such, one or more resource consuming devices can be used to monitor the resources being consumed by the clothes dryer. One or more circuit breakers can incorporate a resource monitoring device so that electrical energy that passes through the circuit breaker can be monitored. Different circuit breakers are generally used to supply electric power to various regions of a structure (e.g., family room lights, kitchen lights, master bedroom wall plugs, etc.) and various major appliances (e.g., kitchen oven, washroom dryer, etc.) or to major power consuming devices (e.g., central air conditioner, floor heaters, etc.). The use of a resource monitor device in a circuit breaker can be used to conveniently monitor certain types of energy consuming devices that may be difficult to individually monitor (e.g., air conditioner, oven furnace, sump pump, etc.). Larger energy consuming devices are typically placed on a single circuit, thus the monitoring of the energy consumption though the circuit is equivalent to monitoring the energy consumption of the larger energy consuming device. Regions in a structure (e.g., bedroom, family room, etc.) are also typically placed on one or more individual circuits, thus the thus the monitoring of the energy consumption though the circuit is equivalent to monitoring the energy consumption in such regions. A resource monitor device can also be incorporated into a power strip, surge protector, and/or extension cord. Power strips, surge protectors, and extension cords are commonly used for electronic and AV equipment. Power strips, surge protectors, and extension cords are also used for other electricity consuming devices. One or more resource monitoring devices can be included in a power strip, surge protector, and/or extension cord. If more than one resource monitoring device is incorporated into a power strip, surge protector, and/or extension cord, each plug receptacle in the power strip, surge protector, and/or extension cord can be monitored; however, this is not required.

Referring again to FIG. 5, all of the resource monitoring devices, modular and/or non-modular devices, are illustrated as wirelessly communicating with a remote monitoring location such as desktop computer 70. As can be appreciated, the remote monitoring location can also or alternatively include other devices such as, but not limited to, cellular phone, IPod, internet, IPad, ITouch, blackberry, laptop computer, tablet, etc.). As can also be appreciated, the one or more of the resource monitoring devices can communication with one than one remote monitoring location. As can be appreciated, one or more of the resource monitoring devices can also or alternately communicate with computer 70 via a wire or cable connection. The computer can be loaded with a variety of circuits, software, etc. designed to receive information from the one or more resource monitoring devices, process information received from the one or more resource monitoring devices, and/or send information to the one or more resource monitoring devices. The computer in FIG. 5 is illustrated as also being connected to the internet so that the computer can access information such as, but not limited to, utility rate, energy prices, energy ratings for resource consuming devices, quality ratings for resource consuming devices, recall and/or repair information for resource consuming devices, proper settings for resource consuming devices, suggested alternatives for resource consuming devices, etc. This information can be processed by the hardware and/or software in the computer to provide a user with 1) real-time resource consumption by one or more resource consuming devices, 2) resource consumption by one or more resource consuming devices over certain periods of time, 3) comparison information between two or more resource consuming devices, 4) comparison information between a resource consuming device and published information regarding the resource consuming device, 5) suggested settings and/or usage times for one or more resource consuming devices to modify resource consumption during a certain time period and/or over a period of time, 6) resource consumption profiles for one or more resource consuming devices that can be used to predict future resource consumption, create a resource consumption plan for a certain period of time, compare actual resource consumption to predicted or planned resource consumption, etc., 7) determine state of Energy Star compliance of one or more resource consuming devices, and/or 8) determine whether one or more resource consuming devices is properly functioning, properly in use, being used to much, beginning to fail and/or has failed. The computer can also be connected to and/or is able to be connected to other portable devices (e.g., IPod, cellular phone, VPN or remote desktop from another computer, etc.) of a user so that the user can a) access information from the computer, b) control the computer regarding the resource monitoring system and/or c) receive warnings and/or updates about one or more resource consuming devices; however, this is not required. The computer can be automatically or manually be connected to a private monitoring service, utility company, and/or other internet locations (e.g., GE website, Maytag website, etc.) so that additional services can be accessed by a user and/or process by the computer (e.g., pay utility bills, obtain utility billing history, monitor and/or report proper and/or abnormal resource consumption by one or more resource consuming devices, obtain product information about one or more resource consuming devices and/or substitutes or alternatives to one or more resource consuming devices, determine Energy Star compliance, etc.). As can be appreciated, computer can be designed and configured to provide any type of information about one or more resource consuming devices.

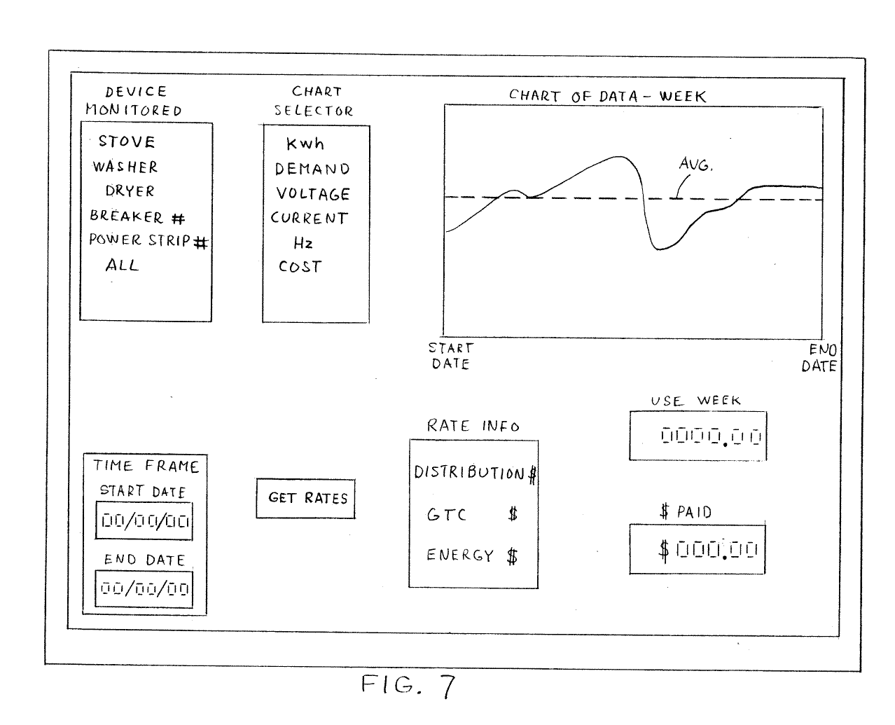

FIG. 7 illustrates a non-limiting screen shot from computer 70. This screen shot illustrates that a user can select resource consumption information by selected resource consuming devices or by all resource consuming devices. Also, the chart selector allows the user to monitor the type of resource being consumed. The chart selector illustrates selections primarily for electricity consumption; however, selections for fluid consumption (e.g., gpm, Ccf, etc.). The screen shot illustrated that a graph can be generated for the user to view resource consumption by one or more resource consuming devices over a certain period of time. As can be appreciated, other or additional types of graphs can be displayed. As also can be appreciated, multiple graphs can be displayed to compare resource consumption between two or more resource consuming devices, between one or more resource consuming devices and predicted resource consumption, between one or more resource consuming devices and desired resource consumption, between one or more resource consuming devices and published resource consumption, etc. The screen shot also illustrates a button to obtain resource rates. Such rates can be average rates, peak rates, future rates, etc. The rate button may enable a user to access rate information from multiple providers to enable a user to change providers. The screen shot also includes cost information for resource consumption and amounts paid for such resource consumption over certain periods of time. As can be appreciated other or alternative information can be displayed on one or more screen shots. The computer software can also be designed to allow a user to customize one or more screen shots. The computer software can also be designed to automatically search and/or input information regarding one or more resource monitoring devices that are in communication with the computer.

Referring now to FIG. 6, there is illustrated a TV 80 that includes a resource monitoring device, which TV is plugged into a standard wall outlet 90. As can be appreciated, the TV could be plugged into a modular resource monitoring device as illustrate din FIGS. 1 and 2, and the modular resource monitoring device is plugged into a standard wall outlet 90. FIG. 6 also illustrated a signal converter 100 plugged into another standard wall outlet 110. Wall outlets 90, 110 are illustrated as being electrically connected. The resource monitoring device is designed to send signals to and/or receive signals from signal converter 100 via the electrical wiring for wall outlets 90, 110. In this configuration, additional wiring is not required to enable the resource monitoring device to communicate with signal converter 100. As such, a preexisting house or structure does not require new cables or wiring to enable one or more resource monitoring device to communicate with signal converter 100. When the circuit breaker box 120 includes one or more resource monitoring devices in the one or more circuit breakers, such one or more resource monitoring devices can also communicate with signal converter 100 via the electrical wiring. Signal converter 100 is connected to computer 70 by a wire or cable and/or wirelessly. The operation of computer 70 in FIG. 6 can be the same or similar to the operation of computer 70 discussed above in FIG. 5.

Set forth below are four (4) configures for a resource monitoring system in a Guest bedroom of a home. RCD is an abbreviation for resource consuming device and RMD is an abbreviation for a resource monitoring device. The examples are non-limiting and are organized from a more complex system (EX 1) to a less complex system (EX 4). As can be appreciated, many other configurations can be used.

| RCD - Guest | | | | |
|---|---|---|---|---|
| Bedroom | RMD - EX 1 | RMD - EX 2 | RMD - EX 3 | RMD - EX 4 |
| Wall Plug 1 | Incorporated in | Incorporated in | None | None |
| | Plug | Plug | | |
| Wall Plug 2 | Incorporated in | Incorporated in | None | None |
| | Plug | Plug | | |
| Wall Plug 3 | Incorporated in | Incorporated in | None | None |
| | Plug | Plug | | |
| Wall Plug 4 | Incorporated in | Incorporated in | None | None |
| | Plug | Plug | | |
| Light Switch 1 for | Incorporated in | Incorporated in | None | None |
| Main Room Lights | Switch | Switch | | |
| Light Switch 2 - To | Incorporated in | Incorporated in | None | None |
| Power Wall Plug 2 | Switch | Switch | | |
| Ceiling Fan Switch | Incorporated in | Incorporated in | None | None |
| for Ceiling Fan | Switch | Switch | | |
| Ceiling Fan Light | Incorporated in | Incorporated in | None | None |
| Switch for Ceiling | Switch | Switch | | |
| Fan Light | | | | |
| Closet Light Switch | Incorporated in | Incorporated in | None | None |
| for Closet Light | Switch | Switch | | |
| Audio System Wall | Incorporated in | Incorporated in | None | None |
| Panel Control | Audio Panel | Audio Panel | | |
| Telephone - | None | None | Modular RMD 1 | Modular RMD 1 |
| Plugged in Wall | | | | |
| Plug 1 | | | | |
| Radio - Plugged in | None | None | Modular RMD 1 | Modular RMD 1 |
| Wall Plug 1 | | | | |
| Bed Lamp 1 - | None | None | Modular RMD 2 | Modular RMD 2 |
| Plugged in Wall | | | | |
| Plug 2 | | | | |
| Bed Lamp 2 - | None | None | Modular RMD 2 | Modular RMD 2 |
| Plugged in Wall | | | | |
| Plug 2 | | | | |
| Floor Lamp 1 - | None | None | Modular RMD 3 | Modular RMD 3 |
| Plugged in Wall | | | | |
| Plug 4 | | | | |
| CO Wall Monitor - | None | None | Modular RMD 3 | Modular RMD 3 |
| Plugged in Wall | | | | |
| Plug 3 | | | | |
| Electrically Wired | Incorporated in | Incorporated in | None | None |
| Ceiling Smoke | Detector | Detector | | |
| Detector | | | | |
| Space Heater - | None | None | Modular RMD 3 | Modular RMD 3 |
| Plugged in Wall | | | | |
| Plug 4 | | | | |
| TV - Plugged in | None | None | Modular RMD 4 | Modular RMD 4 |
| Wall Plug 3 | | | | |
| Bedroom Circuit | Incorporated in | None | Incorporated in | None |
| Breaker 1 for | Circuit Breaker 1 | | Circuit Breaker 1 | |
| Switches and audio | | | | |
| panel control. | | | | |
| Bedroom Circuit | Incorporated in | None | Incorporated in | None |
| Breaker 2 for Plugs | Circuit Breaker 2 | | Circuit Breaker 2 | |
| & Smoke Detector | | | | |

As illustrated above, a bedroom can contain various RCDs. Non-limiting RCDs are set forth above in the left hand column. As can be appreciated, the bedroom can contain a fewer number or greater number of RCDs. As also set forth above, all of the RCDs or a selected number of RCDs can be monitored. A further set forth above, one or more RCDs can be monitored by the same or different type of RMD. Also, one or more RCDs can be monitored by one or more RMDs. The first configuration of EX 1 illustrates that several non-modular RMDs are incorporated in the wall plugs, light switches, audio panel, smoke detector and circuit breakers. The wall plugs each include two plug inlets also include circuitry to individually monitor electricity consumption through each plug inlet so that each RCD plugged into the wall plug can be individually monitored; however, this is not required.

The configuration in EX 1 monitors all electricity consumption in the Guest Bedroom for each RCD via non-modular RMDs. Also, the circuit breakers provide verification for several of the individual RMS. For instance, the sum of electrical energy consumed via all of the switches and audio panel control should be equal to the electrical energy consumption reported by circuit breaker 1.

The configuration in EX 2 is less complex than the configuration in EX 1. The configuration in EX 2 is similar to EX 1 except that there are no RMDs in the circuit breakers for the Guest Bedroom. Similar to the configuration of EX 1, the configuration can be used to individually monitor the electricity consumption of all of the RCDs in the Guest Bedroom.

The configuration in EX 3 is less complex than the configuration in EX 1 and EX 2. In EX 3, the RCDs that are designed to be plugged into the wall plug are all plugged into a modular RMD which in turn is plugged into the wall plug. The individual electrical energy consumption from the lights switches, audio control panel and smoke detector are not monitored. However, the total energy consumption in the Guest Bedroom is monitored via the RMDs in the circuit breakers. As such the electrical energy consumption for the smoke detectors can be determined by taking the electrical energy consumption reported by circuit breaker 2 and subtracting the electrical energy consumption reported by the RMDs that are plugged into wall plugs 1-4. Circuit breaker 1 provides the total electrical energy consumption from the switches and the audio control panel.

The configuration in EX 4 is less complex than the configuration in EX 1, EX 2 and EX 3. The configuration in EX 4 is similar to the configuration of EX 3 except that there are no RMDs in the circuit breakers. As such the configuration of EX 4 only monitors electrical energy consumption from the RCDs that are designed to be plugged into a wall plug. The configuration of EX 4 is very simply and most users can install such a monitoring system with expert assistance.

In each of the examples above, one or more of the RMDs can 1) communicate wirelessly with one or more remote monitoring locations as illustrated in FIG. 5, 2) communicated with one or more remote monitoring locations via the existing electrical wiring for the home as illustrated in FIG. 6, and/or 3) communicated with one or more remote monitoring locations via custom cable and/or wiring connections. More than one remote monitoring location can exist in the home. The user may have one or more computers in the home to monitor one or more RMDs in the home. The home can include one or more wall panels to provide a user information on resource being consumed in one or more locations in the home. As previously mention above, a remote monitoring location can also include a mobile device such as a cell phone or IPad, and/or the information about the RMDs can be transmitted to the internet such that information can be obtain by the user via any device that can connect to the internet.

Set forth below are four (4) configures for a resource monitoring system in a Guest bathroom of a home. The examples are non-limiting and are organized from a more complex system (EX 1) to a less complex system (EX 4). As can be appreciated, many other configurations can be used.

| RCD - Guest | | | | |
|---|---|---|---|---|
| Bathroom | RMD - EX 1 | RMD - EX 2 | RMD - EX 3 | RMD - EX 4 |
| Wall Plug 1 | Incorporated in | Incorporated in | None | None |
| | Plug | Plug | | |
| Wall Plug 2 | Incorporated in | Incorporated in | None | None |
| | Plug | Plug | | |
| Light Switch 1 for | Incorporated in | Incorporated in | None | None |
| Main Bathroom | Switch | Switch | | |
| Lights | | | | |
| Light Switch 2 - for | Incorporated in | Incorporated in | None | None |
| Mirror Lights | Switch | Switch | | |
| Ceiling Fan Switch | Incorporated in | Incorporated in | None | None |
| for Bathroom Fan | Switch | Switch | | |
| Light Switch for | Incorporated in | Incorporated in | None | None |
| Shower Light | Switch | Switch | | |
| Dial Switch for Gas | Incorporated in | Incorporated in | None | None |
| Heater | Switch | Switch | | |
| Audio System Wall | Incorporated in | Incorporated in | None | None |
| Panel Control | Audio Panel | Audio Panel | | |
| Cold Water Supply | Incorporated in | Incorporated in | None | None |
| for Toilet | Supply Line | Supply Line | | |
| Cold Water Supply | Incorporated in | Incorporated in | None | None |
| for Sink | Supply Line | Supply Line | | |
| Hot Water Supply | Incorporated in | Incorporated in | None | None |
| for Sink | Supply Line | Supply Line | | |
| Cold Water Supply | Incorporated in | Incorporated in | None | None |
| for Shower | Supply Line | Supply Line | | |
| Hot Water Supply | Incorporated in | Incorporated in | None | None |
| for Sink | Supply Line | Supply Line | | |
| TV - Plugged in | None | Incorporated in | Modular RMD 2 | Modular RMD 2 |
| Wall Plug 2 | | Supply Line | | |
| Razor/Hair dryer - | None | Incorporated in | Modular RMD 1 | Modular RMD 1 |
| Plugged in Wall | | Supply Line | | |
| Plug 1 | | | | |
| Nightlight - | None | None | Modular RMD 1 | Modular RMD 1 |
| Plugged in Wall | | | | |
| Plug 1 | | | | |
| Bathroom Circuit | Incorporated in | None | Incorporated in | None |
| Breaker 1 for | Circuit Breaker 1 | | Circuit Breaker 1 | |
| Switches | | | | |
| Bathroom Breaker | Incorporated in | None | Incorporated in | None |
| 2 for Plugs | Circuit Breaker 2 | | Circuit Breaker 2 | |
| Main Gas Supply | Incorporated in | None | Incorporated in | None |
| to Building | Supply Line | | Supply Line | |
| Main Gas Supply | Incorporated in | Incorporated in | None | None |
| to Bathroom | Supply Line | Supply Line | | |
| Main Water Supply | Incorporated in | None | Incorporated in | None |
| to Building | Supply Line | | Supply Line | |
| Hot Water Supply | Incorporated in | None | None | None |
| to Building | Supply Line | | | |
| Cold Water Supply | Incorporated in | Incorporated in | None | None |
| to Bathroom | Supply Line | Supply Line | | |
| Hot Water Supply | Incorporated in | Incorporated in | None | None |
| to Bathroom | Supply Line | Supply Line | | |

The configurations for the Guest Bathroom can be more complex due to the additional types of resources that can be potentially monitored. The configurations of EX 1 and EX 2 illustrate a monitoring system that can be used to monitor all of the resources consumed in the Guest Bathroom via non-modular RCDs for electricity consumption. Modular RMDs can be used to monitor the water and gas consumption in the Guest Bathroom; however, this is not required. The configuration of EX 3 monitors the RCDs that are designed to be plugged into the wall plug via modular RMDs. The other electricity consuming devices in the Guest Bathroom are not individually monitored; however, total electricity consumption is monitored via the RMDs in the circuit breakers. The amount of water and gas used in the Guest Bathroom specifically monitored; however, total gas and water consumption for the home is monitored.

The configuration of EX 4 only monitors the RCDs that are designed to be plugged into the wall plug via modular RMDs. All other resource consuming devices in the Guest Bathroom are not monitored. The configuration of EX 4 is very simply and most users can install such a monitoring system with expert assistance.

In each of the examples above, one or more of the RMDs can 1) communicate wirelessly with one or more remote monitoring locations as illustrated in FIG. 5, 2) communicated with one or more remote monitoring locations via the existing electrical wiring for the home as illustrated in FIG. 6, and/or 3) communicated with one or more remote monitoring locations via custom cable and/or wiring connections. More than one remote monitoring location can exist in the home. The user may have one or more computers in the home to monitor one or more RMDs in the home. The home can include one or more wall panels to provide a user information on resource being consumed in one or more locations in the home. As previously mention above, a remote monitoring location can also include a mobile device such as a cell phone or IPad, and/or the information about the RMDs can be transmitted to the internet such that information can be obtain by the user via any device that can connect to the internet.

The invention has been described with reference to the preferred embodiments. These and other modifications of the preferred embodiments as well as other embodiments of the invention will be obvious from the disclosure herein, whereby the foregoing descriptive matter is to be interpreted merely as illustrative of the invention and not as a limitation. It is intended to include all such modifications and alterations insofar as they come within the scope of the appended claims.

I claim:

1. A resource monitoring system that includes a resource monitoring device and a remote resource monitoring location, said resource monitoring device being a) integrated in a resource consuming device, b) connected to a resource consuming device, c) interconnected to a resource consuming device, or combinations thereof, said remote resource monitoring location in communication with said resource monitoring device and providing information to a user concerning a resource being consumed by said resource consuming device.

2. The resource monitoring system as defined in claim 1, wherein said resource monitoring device communicates with said remote resource monitoring location a) wirelessly, b) via a wire or cable connection, c) via the existing electrical wiring of a structure, or combinations thereof.

3. The resource monitoring system as defined in claim 1, wherein said resource monitoring device is designed to monitor electrical energy consumption of said resource consuming device, said resource monitoring device a non-modular device that is integrated in a light switch, a wall plug, a wall control panel, or a circuit breaker.

4. The resource monitoring system as defined in claim 1, wherein said remote resource monitoring location includes a computer and a computer display, said computer including software that is designed to enable a user to a) display information about said resource monitoring device, b) display information about resources consumed by said resource consuming device, or combinations thereof.

5. The resource monitoring system as defined in claim 4, wherein said remote resource monitoring location enables a user to access information about said resource monitoring device, said resource consuming device, or combinations thereof from a location that is remote from said resource monitoring location, said resource monitoring device and said resource consuming device.

6. The resource monitoring system as defined in claim 4, wherein said remote resource monitoring location is designed to a) access an external database that contains rate information for at least one type of resource, and b) process said rate information with information received from said resource monitoring device to provide a user with information about a cost of using said resource consuming device over a defined time period.

7. The resource monitoring system as defined in claim 4, wherein said remote resource monitoring location is designed to access an external database that contains device information about said resource consuming device and a) display said device information to a user on said computer display, b) process said device information and provide information to a user regarding i) proper resource consumption by said resource monitoring device, ii) improper resource consumption by said resource monitoring device, iii) recall notices for said resource monitoring device, iv) warranty notices for resource monitoring device, iv) suggested replacements for said resource monitoring device, and combinations thereof.

8. A method for providing monitoring resource consumption by a resource consuming device comprising:
a) providing a resource monitoring device that monitors resource consumption of said resource consuming devices, said resource monitoring device being i) integrated in a resource consuming device, ii) connected to a resource consuming device, iii) interconnected to a resource consuming device, or combinations thereof; and,
b) providing a remote resource monitoring location that is designed to communicate with said resource monitoring device, said remote resource monitoring location designed to process information received from said resource monitoring device and to provide information to a user regarding said resource consumption by said resource consuming device.

9. The method as defined in claim 8, wherein said resource monitoring device communicates with said remote resource monitoring location a) wirelessly, b) via a wire or cable connection, c) via the existing electrical wiring of a structure, or combinations thereof.

10. The method as defined in claim 8, wherein said resource monitoring device is designed to monitor electrical energy consumption of said resource consuming device, said resource monitoring device a non-modular device that is integrated in a light switch, a wall plug, a wall control panel, or a circuit breaker.

11. The method as defined in claim 8, wherein said remote resource monitoring location includes a computer and a computer display, said computer including software that is designed to enable a user to a) display information about said resource monitoring device, b) display information about resources consumed by said resource consuming device, or combinations thereof.

12. The method as defined in claim 11, wherein said remote resource monitoring location enables a user to access information about said resource monitoring device, said resource consuming device, or combinations thereof from a location that is remote from said resource monitoring location, said resource monitoring device and said resource consuming device.

13. The method as defined in claim 11, wherein said remote resource monitoring location is designed to a) access an external database that contains rate information for at least one type of resource, and b) process said rate information with information received from said resource monitoring device to provide a user with information about a cost of using said resource consuming device over a defined time period.

14. The method as defined in claim 11, wherein said remote resource monitoring location is designed to access an external database that contains device information about said resource consuming device and a) display said device information to a user on said computer display, b) process said device information and provide information to a user regarding i) proper resource consumption by said resource monitoring device, ii) improper resource consumption by said resource monitoring device, iii) recall notices for said resource monitoring device, iv) warranty notices for resource monitoring device, iv) suggested replacements for said resource monitoring device, and combinations thereof.

15. The method as defined in claim 8, wherein said resource monitoring device obtains information regarding Energy Star compliance of a resource consuming device, said resource consuming device designed to provide information to a user regarding Energy Star compliance of a resource consuming device by one or more arrangements selected from the group consisting of an audio signal, a visual signal, information on a display, and transmitting information to a remote monitoring location for display on said remote monitoring location.

16. The method as defined in claim 8, wherein said resource monitoring device is programmable to enable a user to input information regarding one or more information types selected from the group consisting of type of said resource consuming device, location of said resource consuming device, model of said resource consuming device, date information, time information, resource rate information, Energy Star information about said resource consuming device, operating times of said resource consuming device, and proper operating parameters of said resource consuming device, said resource monitoring device programmable by one or more arrangements selected from the group consisting of connecting an information or database to said resource monitoring device, manually inputting information in said resource monitoring device, and remote programming of said resource monitoring device via said remote monitoring location.
